(19) United States
(12) Patent Application Publication
(10) Pub. No.: US 2026/0271188 A1
(43) Pub. Date: Sep. 10, 2026

(54) CIRCUIT BOARD AND MANUFACTURING METHOD THEREOF

(71) Applicant: SAMSUNG ELECTRO-MECHANICS CO., LTD., Suwon-si (KR)

(72) Inventors: Kyunghwan Ko, Suwon-si (KR); Hyojin Cha, Suwon-si (KR); Woodeug Park, Suwon-si (KR); Sanghoon Kim, Suwon-si (KR)

(73) Assignee: SAMSUNG ELECTRO-MECHANICS CO., LTD., Suwon-si (KR)

(21) Appl. No.: 19/312,977

(22) Filed: Aug. 28, 2025

(30) Foreign Application Priority Data
Mar. 4, 2025 (KR) 10-2025-0027516

(51) Int. Cl. H05K 1/11; H05K 1/02; H05K 3/42

(52) U.S. Cl. CPC H05K 1/115; H05K 1/0298; H05K 3/42

(57) ABSTRACT

A circuit board according to an embodiment may include a first insulating layer, a first circuit wiring disposed inside a first area of the first insulating layer, a plurality of vias connected to the first circuit wiring, a second circuit wiring disposed on a second area of the first insulating layer, a bridge substrate disposed on the first area and having a plurality of first conductive pads, a plurality of conductive adhesive members electrically connecting the plurality of vias to the plurality of first conductive pads, and a second insulating layer covering the second circuit wiring and the bridge substrate on the first insulating layer.

### CROSS-REFERENCE TO RELATED APPLICATION

This application claims priority to and the benefit of Korean Patent Application No. 10-2025-0027516 filed with the Korean Intellectual Property Office on Mar. 4, 2025, the entire contents of which are incorporated herein by reference.

### BACKGROUND

### 1. Field of the Invention

The present disclosure relates to a circuit board and a manufacturing method thereof.

### 2. Description of the Related Art

With the recent development of electronic devices, methods for implementing ultra-fine semiconductor circuits are being introduced in the semiconductor front-end process, the rear-end process, and the packaging process.

In particular, in a high-performance packaging structure, a structure is being developed to form a redistribution layer (RDL) directly on the substrate or to embed a separate bridge substrate to which a microcircuit is applied.

In a structure where a bridge substrate is embedded in a substrate, it is easy to connect the upper circuit wiring of the substrate and the wiring of the bridge substrate, but it is difficult to connect the lower circuit wiring of the substrate and the wiring of the bridge substrate.

Therefore, it is difficult to transmit power and signals from the lower circuit wiring of the substrate to the bridge substrate with the shortest distance. In addition, some chips located on the bridge substrate also need to transmit power and signals by bypassing the bridge substrate from the lower circuit wiring of the substrate, making it difficult to transmit power and signals through the shortest distance, and since separate bypass wiring for power and signal transmission is required, the wiring length increases, which may reduce the efficiency of power integrity and signal integrity.

### SUMMARY

Embodiments provide a circuit board and a manufacturing method thereof that can maximize the efficiency of power integrity and signal integrity by shortening the length of wiring for power and signal transmission by directly connecting a bridge substrate and a circuit wiring under it.

However, the problem to be solved by embodiments of the present disclosure is not limited to the above-described problems and can be variously extended within the scope of the technical concept included in the present disclosure.

A circuit board according to an embodiment may include a first insulating layer, a first circuit wiring disposed inside a first area of the first insulating layer, a plurality of vias connected to the first circuit wiring, a bridge substrate disposed on the first area and having a plurality of first conductive pads, a plurality of conductive adhesive members electrically connecting the plurality of vias to the plurality of first conductive pads, and a second insulating layer covering the bridge substrate on the first insulating layer.

The circuit board may further include an underfill filling between the first area of the first insulating layer and the bridge substrate.

The plurality of vias may include a plating layer.

The via may be disposed inside the first insulating layer, and an upper surface of the via may be located on substantially the same plane as an upper surface of the first insulating layer.

The first insulating layer comprises a step area.

The via may protrude to the outside of the first insulating layer.

Aa side surface of the via may be in contact with the conductive adhesive member.

The plurality of vias may include a solder layer.

The circuit board may further include a second circuit wiring disposed on a second area of the first insulating layer, and a third circuit wiring disposed on the second insulating layer and electrically connected to a plurality of the second conductive pads of the bridge substrate.

In addition, a manufacturing method of a circuit board according to an embodiment may include forming a first circuit wiring inside a first area of a first insulating layer, forming a plurality of vias connected to the first circuit wiring, forming a plurality of conductive members on the plurality of the vias, contacting a first conductive pad of a bridge substrate with the plurality of conductive members, and forming a second insulating layer covering the bridge substrate on the first insulating layer.

The method of the circuit board may further include forming an underfill by filling between the first area of the first insulating layer and the bridge substrate. Forming the plurality of vias may include forming a plurality of via holes in the first insulating layer and completing the via by forming a plurality of via layers protruding above an upper surface of the first insulating layer in the plurality of via holes through a plating process.

Forming the plurality of vias may further include completing the via by removing the via layers protruding above the upper surface of the first insulating layer through a grinding process, and an upper surface of the via may be located on substantially the same plane as the upper surface of the first insulating layer.

The manufacturing method of the circuit board may further include forming a step area by etching a portion of the first area of the first insulating layer.

The via may protrude to the outside of the first insulating layer by forming the step area.

Forming the plurality of vias may include forming a plurality of via holes in the first insulating layer and completing the via by forming a solder layer in the plurality of the via holes through a printing process, and an upper surface of the via may be disposed on substantially the same plane as an upper surface of the first insulating layer.

The manufacturing method of the circuit board may further include forming a second circuit wiring on a second area of the first insulating layer, and forming a third circuit wiring electrically connected to a plurality of the second conductive pads of the bridge substrate on the second insulating layer.

According to embodiments, by directly connecting the bridge substrate and the circuit wiring under it, the length of the wiring for power and signal transmission can be shortened to maximize the efficiency of power integrity and signal integrity.

However, it is obvious that the effects of the embodiments are not limited to the above-described effects and may be variously extended without departing from the concept and scope of the present disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a cross-sectional view of a circuit board according to an embodiment.

FIG. 2 is a schematic flow chart of a manufacturing method of a circuit board according to an embodiment.

FIGS. 3, 4, 5, 6, 7 and 8 are cross-sectional views sequentially illustrating a manufacturing method of the circuit board of FIG. 2.

FIG. 9 is a cross-sectional view of a circuit board according to another embodiment.

FIG. 10 is a cross-sectional view of a circuit board according to yet another embodiment.

FIGS. 11 and 12 are cross-sectional views illustrating some steps of a manufacturing method of the circuit board of FIG. 10.

FIG. 13 is a cross-sectional view of a circuit board according to yet another embodiment.

FIGS. 14 and 15 are cross-sectional views illustrating some steps of a manufacturing method of the circuit board of FIG. 13.

FIG. 16 is a cross-sectional view of a circuit board according to yet another embodiment.

FIGS. 17 and 18 are cross-sectional views illustrating some steps of a manufacturing method of the circuit board of FIG. 16.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. The present disclosure may be implemented in various different forms and is not limited to the embodiments described herein.

In order to clearly describe the present disclosure, parts unrelated to the description are omitted in the drawings, and the same reference numerals are designated to the same or similar elements throughout the specification.

In addition, accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

Furthermore, the size and thickness of each element shown in the drawing are arbitrarily shown for convenience of explanation, and present disclosure is not necessarily limited to those shown. In the drawings, the thickness of layers, films, panels, regions, areas etc., are exaggerated for clarity. And in the drawings, for convenience of explanation, the thickness of some layers and areas are exaggerated.

Furthermore, it will be understood that when an element such as a layer, film, region, area or substrate is referred to as being “on” another element, it can be directly on the other element or intervening elements may also be present. In contrast, when an element is referred to as being “directly on” another element, there are no intervening elements present. Furthermore, the word “on” or “above” means positioned on or below the object portion and does not necessarily mean positioned on the upper side of the object portion based on a gravitational direction.

Furthermore, throughout the specification, unless explicitly described to the contrary, the word “comprise” and variations such as “comprises” or “comprising” will be understood to imply the inclusion of stated elements but not the exclusion of any other elements.

Furthermore, throughout the specification, the phrase “in a plan view” means when an object portion is viewed from above, and the phrase “in a cross-sectional view” means when a cross-section taken by vertically cutting an object portion is viewed from the side.

Throughout the specification, “connected” means that two or more components are not only directly connected, but two or more components may be connected indirectly through other components, physically connected as well as being electrically connected, or it may be referred to by different names depending on the location or function but may mean integral.

Furthermore, throughout the specification, the expression “substantially same” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

Hereinafter, various embodiments and modified embodiments will be described in detail with reference to the drawings.

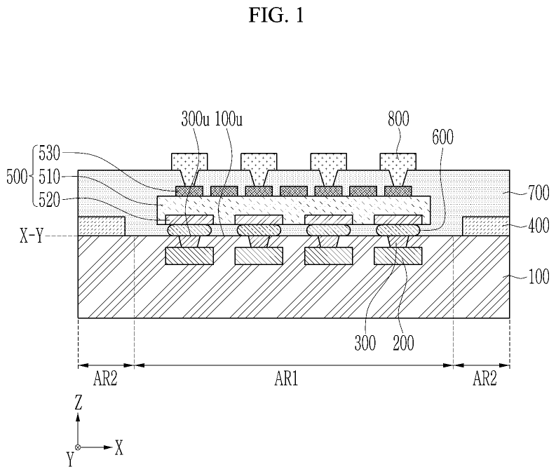

Referring to FIG. 1, a circuit board according to an embodiment will be described.

FIG. 1 is a cross-sectional view of a circuit board according to an embodiment.

As illustrated in FIG. 1, the circuit board according to the embodiment may include a first insulating layer 100, a first circuit wiring 200, a plurality of vias 300, a second circuit wiring 400, a bridge substrate 500, a plurality of conductive adhesive members 600, a second insulating layer 700, and a third circuit wiring 800. Here, the upper and lower positional relationships are set based on the Z direction. That is, position relationships such as top, down, upper surface, and lower surface are set based on the Z direction.

The first insulating layer 100 may include a thermosetting resin such as an epoxy resin and polyimide, a thermoplastic resin such as polyethylene (PE), polycarbonate (PC), and polyvinyl chloride (PVC), or a composite resin such as prepreg or ABF (Ajinomoto Buildup Film) in which a reinforcing material such as glass fiber or inorganic filler is impregnated.

The first circuit wiring 200 may be disposed inside a first area AR1 of the first insulating layer 100. The first circuit wiring 200 may be a lower circuit wiring 200 located below the bridge substrate 500 based on the bridge substrate 500. The first circuit wiring 200 may transmit an electrical signal. The first circuit wiring 200 may be arranged in various patterns and may be arranged as a plurality of layers. In the present embodiment, a structure in which one layer of first circuit wiring 200 is located inside the first insulating layer 100 is illustrated, but the present embodiment is not limited thereto, and a structure in which various numbers of first circuit wirings 200 are located inside the first insulating layer 100 is also possible. The first circuit wiring 200 may include a conductive material such as copper (Cu), aluminum (Al), silver (Ag), tin (Sn), gold (Au), nickel (Ni), lead (Pb), titanium (Ti), or alloys thereof.

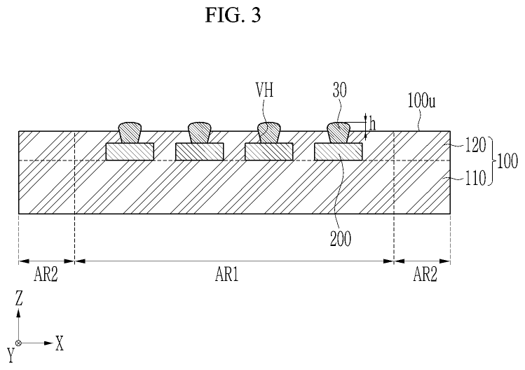

The plurality of vias 300 may be connected to the first circuit wiring 200. The plurality of vias 300 may include a plating layer 30 (see FIG. 3) formed by a plating process. The plurality of vias 300 may be located inside the first insulating layer 100, and an upper surface 300u of the plurality of vias 300 may be flat. In this case, the upper surface 300u of the plurality of vias 300 may be located on the same plane (X-Y plane) as the upper surface 100u of the first insulating layer 100.

The second circuit wiring 400 may be disposed on a second area AR2 of the first insulating layer 100. The second circuit wiring 400 also transmits an electrical signal and may be arranged in various patterns. The second circuit wiring 400 may include a conductive material such as copper (Cu), aluminum (Al), silver (Ag), tin (Sn), gold (Au), nickel (Ni), lead (Pb), titanium (Ti), or alloys thereof.

The bridge substrate 500 may be disposed in the first area AR1 and may implement a microcircuit pattern.

The bridge substrate may include a bridge body 510, a plurality of first conductive pads 520, and a plurality of second conductive pads 530.

The bridge body 510 may include a bridge insulating layer (not shown) made of silicon or polymer, and the like, and a bridge circuit wiring (not shown) having a smaller wiring width than the first circuit wiring 200. Microcircuit patterns may be implemented by the bridge circuit wiring (not shown).

The plurality of first conductive pads 520 may be disposed on a lower surface of the bridge body 510. Although the present embodiment shows a structure in which the plurality of first conductive pads 520 are buried in the bridge body 510, the present embodiment is not limited thereto, and a structure in which the plurality of first conductive pads 520 protrude to the outside of the bridge body 510 may be also possible.

The plurality of second conductive pads 530 may be disposed on an upper surface of the bridge body 510. Although the present embodiment shows a structure in which the plurality of second conductive pads 530 protrude to the outside of the bridge body 510, the present embodiment is not limited thereto, and a structure in which the plurality of second conductive pads 530 is buried in the bridge body 510 may be also possible.

The plurality of conductive adhesive members 600 may be disposed between the first insulating layer 100 and the bridge substrate 500 and may electrically connect the plurality of vias 300 to the plurality of first conductive pads 520. The conductive adhesive member 600 may include a solder ball or the like.

In this way, by directly connecting the first circuit wiring 200 and the bridge substrate 500 using the plurality of conductive adhesive members 600 and the plurality of vias 300, power and signals can be directly transmitted to the bridge substrate 500, thereby shortening the length of the wiring for transmitting power and signals. Therefore, the efficiency of power integrity and signal integrity can be maximized.

The second insulating layer 700 may cover the second circuit wiring 400 and the bridge substrate 500 on the first insulating layer 100. The second insulating layer 700 may include a thermosetting resin such as an epoxy resin and polyimide, a thermoplastic resin such as polyethylene (PE), polycarbonate (PC), and polyvinyl chloride (PVC), or a composite resin such as prepreg or ABF (Ajinomoto Buildup Film) in which a reinforcing material such as glass fiber or inorganic filler is impregnated.

The second insulating layer 700 may cover the bridge substrate 500 to fill a space between the first insulating layer 100 and the bridge substrate 500. Therefore, the second insulating layer 700 may be in contact with the conductive adhesive member 600 and may also fill a space between the adjacent conductive adhesive members 600.

The third circuit wiring 800 may be disposed on the second insulating layer 700 and may be electrically connected to the plurality of second conductive pads 530 of the bridge substrate 500. The third circuit wiring may be a upper circuit wiring 800 located above the bridge substrate 500 based on the bridge substrate 500.

Hereinafter, a manufacturing method of a circuit board according to an embodiment will be described in detail with reference to FIG. 1 and FIGS. 2 to 8.

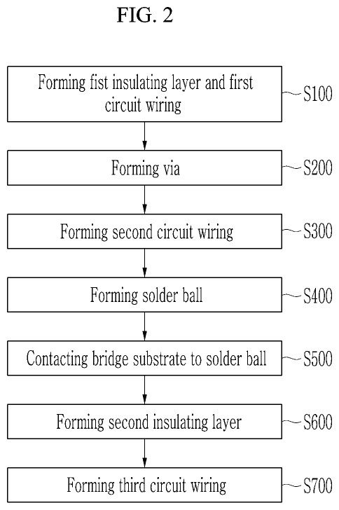

FIG. 2 is a schematic flow chart of a manufacturing method of a circuit board according to an embodiment, and FIGS. 3 to 8 are cross-sectional views sequentially illustrating a manufacturing method of the circuit board of FIG. 2.

First, as illustrated in FIGS. 2 and 3, the first insulating layer 100 may be formed, and the first circuit wiring 200 may be formed inside the first area AR1 of the first insulating layer 100 (S100). That is, a first sub-insulating layer 110 that is a portion of the first insulating layer 100 may be formed, the first circuit wiring 200 may be formed on the first sub-insulating layer 110, and a second sub-insulating layer 120 may be formed to cover the first circuit wiring 200. The first sub-insulating layer 110 may form the first insulating layer 100 together with the second sub-insulating layer 120.

Next, the plurality of vias 300 connected to the first circuit wiring 200 may be formed using a plating process (S200).

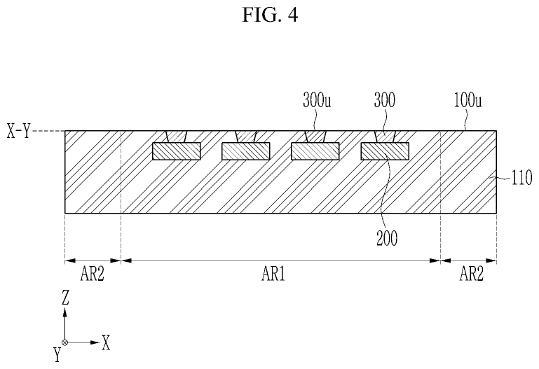

That is, as illustrated in FIG. 3, a plurality of via holes VH may be formed in the first insulating layer 100, and a plurality of via layers 30 may be formed in each of the plurality of via holes VH through a plating process. Here, the plurality of via layers 30 may protrude above the upper surface 100u of the first insulating layer 100. In this case, since the plurality of via layers 30 may be formed through a plating process, the heights (h) of the plurality of via layers 30 based on the upper surface 100u of the first insulating layer 100 may be uneven. Therefore, as illustrated in FIG. 4, the plurality of vias 300 may be completed by removing a portion of the plurality of via layers 30 protruding above the upper surface 100u of the first insulating layer 100 through a grinding process. Therefore, the upper surface 300u of the plurality of vias 300 may be flat, and the upper surface 300u of the plurality of vias 300 may be located on substantially the same plane (X-Y plane) as the upper surface 100u of the first insulating layer 100.

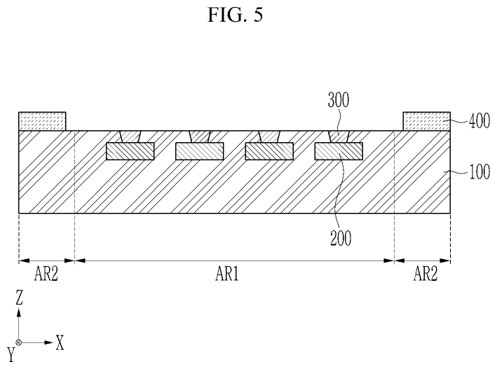

Next, as illustrated in FIGS. 2 and 5, the second circuit wiring 400 may be formed on the first insulating layer 100 of the second area AR2 (S300). The second circuit wiring 400 may be formed to correspond to the second area AR2 of the first insulating layer 100 not located on the bridge substrate 500.

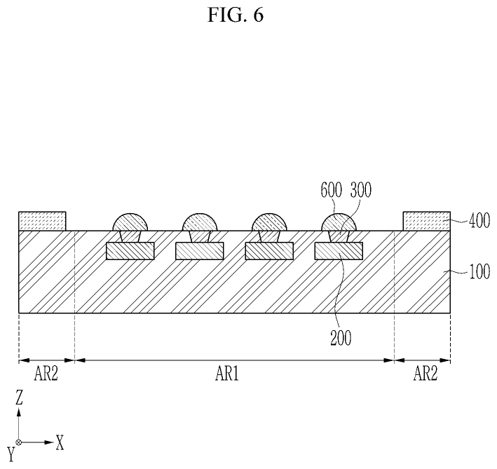

Next, as illustrated in FIGS. 2 and 6, the plurality of conductive adhesive members 600 may be formed on the plurality of vias 300, respectively (S400). The conductive adhesive member 600 may include a solder ball or the like.

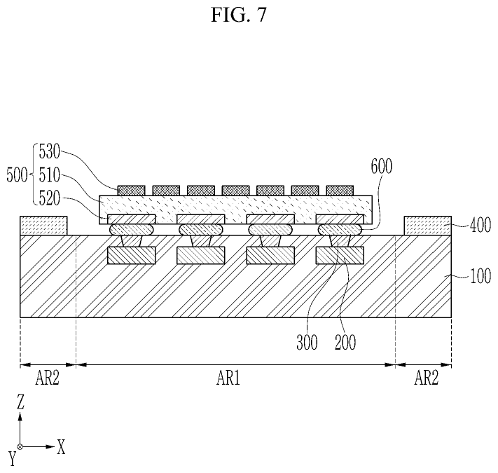

Next, as illustrated in FIGS. 2 and 7, the bridge substrate 500 may be positioned corresponding to the first area AR1 of the first insulating layer 100, and the plurality of first conductive pads 520 of the bridge substrate 500 and the plurality of conductive adhesive members 600 may be brought into contact with each other and pressurized to combine the plurality of first conductive pads 520 of the bridge substrate 500 and the plurality of conductive adhesive members 600 (S500). In this case, the plurality of conductive adhesive members 600 may be deformed into a crushed shape by being pressed.

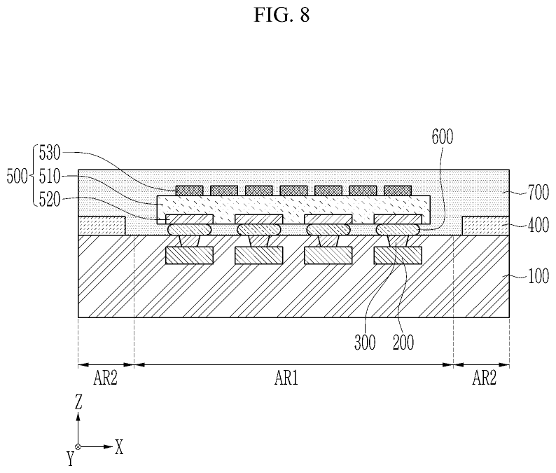

Next, as illustrated in FIG. 2 and FIG. 8, the second insulating layer 700 covering the second circuit wiring 400 and the bridge substrate 500 may be formed on the first insulating layer 100 (S600). In this case, the second insulating layer 700 may cover the bridge substrate 500 and fill a space between the first insulating layer 100 and the bridge substrate 500 to strongly couple the bridge substrate 500 to the first insulating layer 100.

Next, as illustrated in FIGS. 1 and 2, the third circuit wiring 800 electrically connected to the plurality of second conductive pads 530 of the bridge substrate 500 may be formed on the second insulating layer 700 (S700). That is, the via hole VH exposing a portion of the plurality of second conductive pads 530 may be formed in the second insulating layer 700, and the third circuit wiring 800 may be formed in the via hole VH by using a plating process and a photo etching process.

Meanwhile, in the above embodiment, the second insulating layer covers the bridge substrate and fills the space between the first insulating layer and the bridge substrate, but another embodiment of filling the space between the first insulating layer and the bridge substrate with an underfill may be possible.

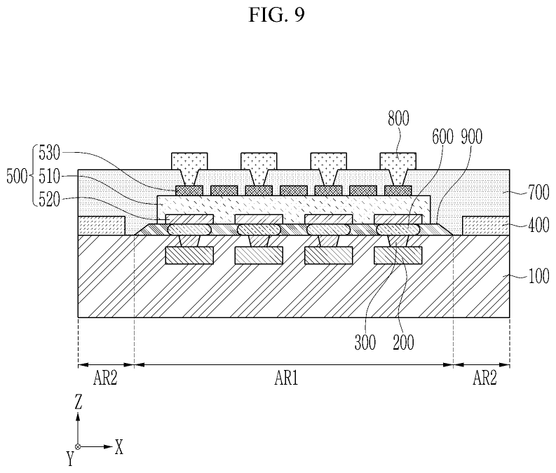

Hereinafter, a circuit board according to another embodiment will be described in detail with reference to FIG. 9.

FIG. 9 is a cross-sectional view of a circuit board according to another embodiment.

The embodiment illustrated in FIG. 9 is substantially the same as the embodiment illustrated in FIG. 1 except for the underfill, and thus repeated descriptions thereof will be omitted.

As illustrated in FIG. 9, the circuit board according to another embodiment may include the first insulating layer 100, the first circuit wiring 200, the plurality of vias 300, the second circuit wiring 400, the bridge substrate 500, the plurality of conductive adhesive members 600, the second insulating layer 700, the third circuit wiring 800, and an underfill 900.

The underfill 900 may fill a space between the first area AR1 of the first insulating layer 100 and the bridge substrate 500. The underfill 900 may be made of a material such as an epoxy resin and may be supplied in a liquid state.

Therefore, the underfill 900 may contact the conductive adhesive member 600, minimize the occurrence of voids in the space between the adjacent conductive adhesive members 600, and more completely fill the space between the adjacent conductive adhesive members 600.

In this way, the bridge substrate 500 may be more strongly coupled to the first insulating layer 100 by filling the space between the first insulating layer 100 and the bridge substrate 500 using the underfill 900. Furthermore, the underfill 900 may have high thermal conductivity, and thus may effectively disperse heat generated from the bridge substrate 500.

Meanwhile, in another embodiment of FIG. 9, the upper surface of the plurality of vias is located on substantially the same plane as the upper surface of the first insulating layer and the space between the first insulating layer and the bridge substrate fills with an underfill, however other embodiment of filling the first insulating layer and the bridge substrate with underfill while a plurality of vias protrude outside the first insulating layer may be also possible.

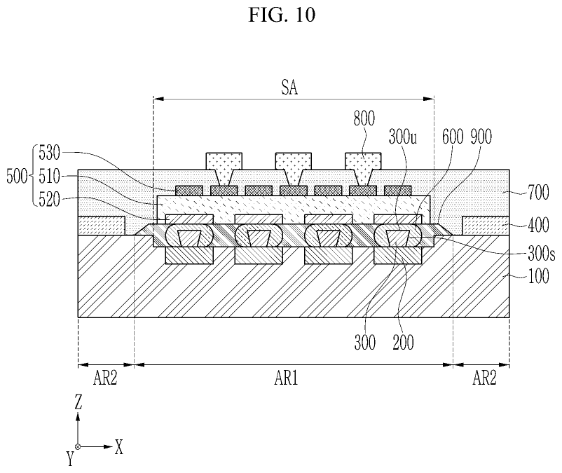

Hereinafter, a circuit board according to yet another embodiment will be described in detail with reference to FIG. 10.

FIG. 10 is a cross-sectional view of a circuit board according to yet another embodiment.

The embodiment illustrated in FIG. 10 is substantially the same as the embodiment illustrated in FIG. 9 except for the structure of the first insulating layer and the plurality of vias, and thus a repeated description thereof will be omitted.

As illustrated in FIG. 10, the circuit board according to yet another embodiment may include the first insulating layer 100, the first circuit wiring 200, the plurality of vias 300, the second circuit wiring 400, the bridge substrate 500, the plurality of conductive adhesive members 600, the second insulating layer 700, the third circuit wiring 800, and the underfill 900.

The first area AR1 of the first insulating layer 100 may have a step area SA. The step area SA may be an area recessed by a predetermined depth (d) from the upper surface 100u of the first insulating layer 100.

The first circuit wiring 200 may be disposed inside the first area AR1 of the first insulating layer 100.

The plurality of vias 300 may be connected to the first circuit wiring 200. The plurality of vias 300 may protrude above the upper surface 100u of the first insulating layer 100. The upper surface 300u of the plurality of vias 300 may be flat. In this case, a side surface 300s of the via may be in contact with the conductive adhesive member 600 and may be covered by the conductive adhesive member 600. By increasing a contact area between the conductive adhesive member 600 and the via 300, a bonding force between the conductive adhesive member 600 and the via 300 may be improved.

The underfill 900 may fill the space between the first area AR1 of the first insulating layer 100 and the bridge substrate 500. Since the underfill 900 is filled in the step area SA of the first insulating layer 100, the occurrence of voids in the space between adjacent conductive adhesive members 600 may be minimized, and the space between adjacent conductive adhesive members 600 may be more completely filled. In some embodiments, a thickness of the underfill 900 changes between an edge of the step area SA and an edge of the first area AR1.

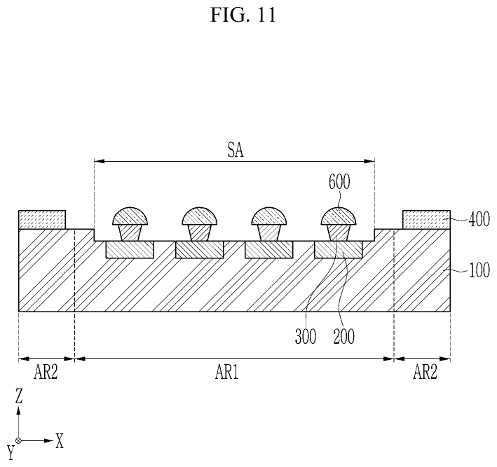

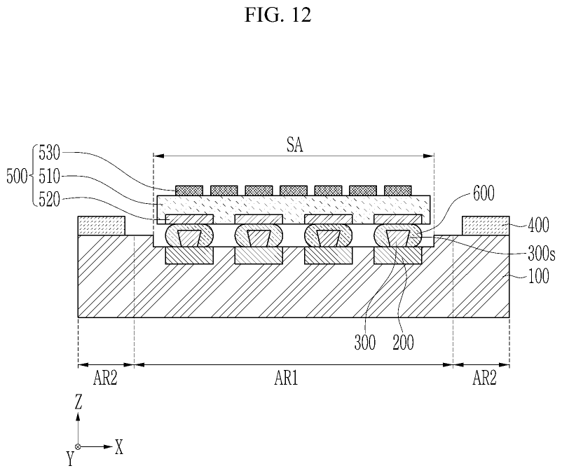

Then, a manufacturing method of a circuit board according to an embodiment will be described below in detail with reference to FIGS. 11 and 12 together with FIG. 10.

FIGS. 11 and 12 are cross-sectional views illustrating some steps of a manufacturing method of the circuit board of FIG. 10.

As illustrated in FIG. 11, the first insulating layer 100 may be formed, and the first circuit wiring 200 may be formed inside the first area AR1 of the first insulating layer 100. Then, the plurality of vias 300 connected to the first circuit wiring 200 may be formed using a plating process. In addition, the second circuit wiring 400 may be formed on the first insulating layer 100 of the second area AR2. The step area SA may be formed by etching a portion of the first area AR1 of the first insulating layer 100 using a plasma etching method or a laser processing method. In this case, the plurality of vias 300 may protrude above the upper surface 100u of the first insulating layer 100. Furthermore, the plurality of conductive adhesive members 600 may be formed on a plurality of vias (300), respectively.

Next, as illustrated in FIG. 12, the bridge substrate 500 may be positioned corresponding to the first area AR1 of the first insulating layer 100, and the plurality of first conductive pads 520 of the bridge substrate 500 and the plurality of conductive adhesive members 600 may be brought into contact with each other and pressurized to combine the plurality of first conductive pads 520 of the bridge substrate 500 and the plurality of conductive adhesive members 600. In this case, the plurality of conductive adhesive members 600 may be pressed to cover the side surface 300s of the via 300.

Next, as illustrated in FIG. 10, the underfill 900 may be formed to fill the space between the first area AR1 of the first insulating layer 100 and the bridge substrate 500. In addition, the second circuit wiring 400 and the second insulating layer 700 covering the bridge substrate 500 may be formed on the underfill 900. Additionally, the third circuit wiring 800 electrically connected to the plurality of second conductive pads 530 of the bridge substrate 500 may be formed on the second insulating layer 700.

Meanwhile, in yet another embodiment of FIG. 10, the plurality of vias protrude outside the first insulating layer with the step area formed in the first insulating layer, however other embodiment may be possible in which the plurality of vias protrude outside the first insulating layer without the step area formed in the first insulating layer.

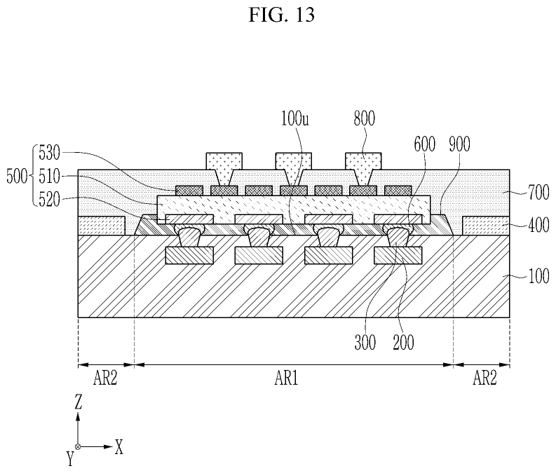

Hereinafter, a circuit board according to yet another embodiment will be described in detail with reference to FIG. 13.

FIG. 13 is a cross-sectional view of a circuit board according to yet another embodiment.

The embodiment illustrated in FIG. 13 may be substantially the same as the embodiment illustrated in FIG. 9 except for the structure of the plurality of vias, and thus a repeated description thereof will be omitted.

As illustrated in FIG. 13, the circuit board according to yet another embodiment may include the first insulating layer 100, the first circuit wiring 200, the plurality of vias 300, the second circuit wiring 400, the bridge substrate 500, the plurality of conductive adhesive members 600, the second insulating layer 700, the third circuit wiring 800, and the underfill 900.

The first insulating layer 100 does not have a step area and may have a flat upper surface 100u.

The first circuit wiring 200 may be disposed inside the first area AR1 of the first insulating layer 100.

The plurality of vias 300 may be connected to the first circuit wiring 200. A portion of the plurality of vias 300 may protrude above the upper surface 100u of the first insulating layer 100. In this case, a portion of the side surface 300s of the via may be in contact with the conductive adhesive member 600 and may be covered by the conductive adhesive member 600. In addition, the upper surface 300u of the via 300 may have a convex shape without having a flat shape.

As described above, since a portion of the via 300 protrudes above the upper surface 100u of the first insulating layer 100, a contact area between the conductive adhesive member 600 and the via 300 may be increased, a bonding force between the conductive adhesive member 600 and the via 300 may be improved.

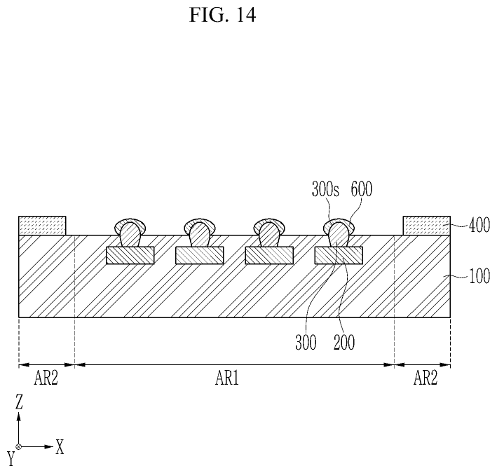

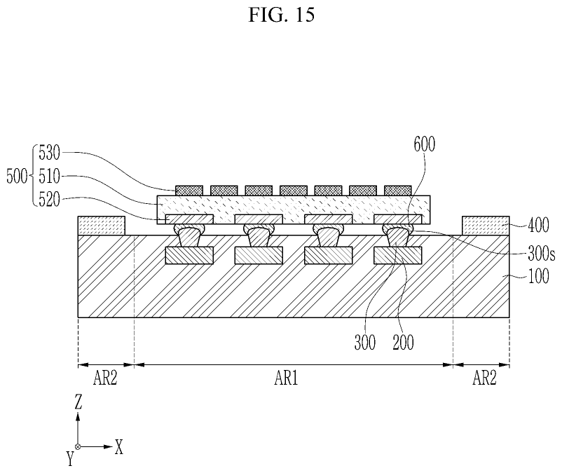

Then, a manufacturing method of a circuit board according to another embodiment will be described in detail below with reference to FIGS. 14 and 15 together with FIG. 13.

FIGS. 14 and 15 are cross-sectional views illustrating some steps of a manufacturing method of the circuit board of FIG. 13.

As illustrated in FIG. 14, the first insulating layer 100 may be formed, and the first circuit wiring 200 may be formed inside the first area AR1 of the first insulating layer 100. Then, the plurality of vias 300 connected to the first circuit wiring 200 may be formed using a plating process. In this case, a portion of the plurality of vias 300 may protrude above the upper surface 100u of the first insulating layer 100. In addition, the second circuit wiring 400 may be formed on the first insulating layer 100 of the second area AR2. Furthermore, the plurality of conductive adhesive members 600 may be formed on a plurality of vias 300, respectively.

Next, as illustrated in FIG. 15, the bridge substrate 500 may be positioned corresponding to the first area AR1 of the first insulating layer 100, and the plurality of first conductive pads 520 of the bridge substrate 500 and the plurality of conductive adhesive members 600 may be brought into contact with each other and pressurized to combine the plurality of first conductive pads 520 of the bridge substrate 500 and the plurality of conductive adhesive members 600. The plurality of conductive adhesive members 600 may be pressurized to cover a portion of the side surface 300s of the via 300 that protrudes above the upper surface 100u of the first insulating layer 100.

As illustrated in FIG. 13, the underfill 900 may be formed to fill between the first area AR1 of the first insulating layer 100 and the bridge substrate 500. In addition, the second insulating layer 700 may be formed on the underfill 900 to cover the second circuit wiring 400 and the bridge substrate 500. Additionally, the third circuit wiring 800 electrically connected to the plurality of second conductive pads 530 of the bridge substrate 500 is formed on the second insulating layer 700.

As described above, by forming the conductive adhesive member 600 while the plurality of vias 300 formed by the plating process protrude to the outside of the first insulating layer 100, it is not necessary to use a separate grinding process for flattening the plurality of vias 300, thereby reducing manufacturing costs and increasing the contact area between the vias 300 and the conductive adhesive member 600 to improve conductivity and bonding strength.

Meanwhile, in the embodiment of FIG. 9, the plurality of vias are made of a plating layer formed by a plating process, but other embodiments may be possible in which a plurality of vias are made of a solder layer formed by a printing process.

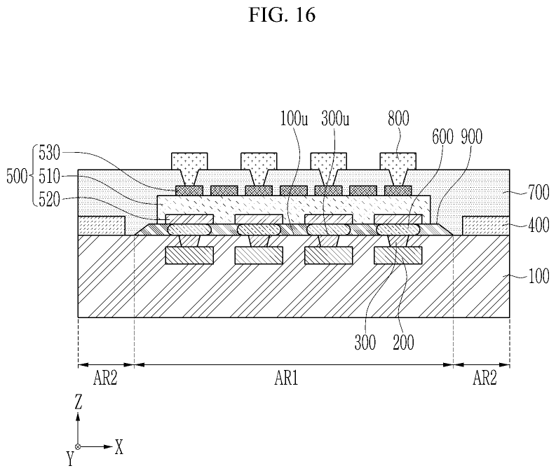

Hereinafter, a circuit board according to yet another embodiment will be described in detail with reference to FIG. 16.

FIG. 16 is a cross-sectional view of a circuit board according to yet another embodiment.

The embodiment illustrated in FIG. 16 may be substantially the same as the embodiment illustrated in FIG. 9 except for the structure of the plurality of vias, and thus a repeated description thereof will be omitted.

As illustrated in FIG. 16, the circuit board according to yet another embodiment may include the first insulating layer 100, the first circuit wiring 200, the plurality of vias 300, the second circuit wiring 400, the bridge substrate 500, the plurality of conductive adhesive members 600, the second insulating layer 700, the third circuit wiring 800, and the underfill 900.

The first insulating layer 100 does not have a step area and may have a flat upper surface 100u.

The first circuit wiring 200 may be disposed inside the first area AR1 of the first insulating layer 100.

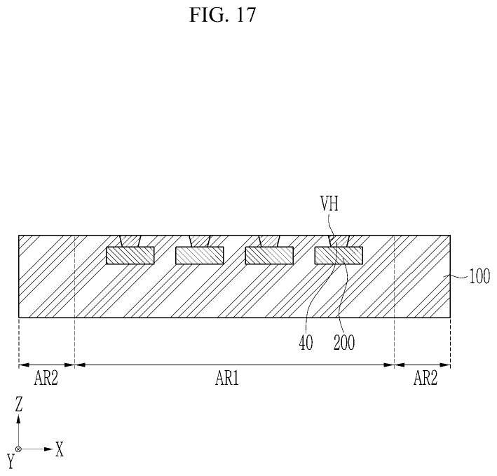

The plurality of vias 300 may be connected to the first circuit wiring 200. The plurality of vias 300 may include a solder layer 40 (see FIG. 17) formed by a printing process. The via 300 may be formed of substantially the same material as the conductive adhesive member 600.

The plurality of vias 300 may be disposed inside the first insulating layer 100, and the upper surface 300u of the plurality of vias 300 may be flat. In this case, the upper surface 300u of the plurality of vias 300 may be positioned on substantially the same plane (X-Y plane) as the upper surface 100u of the first insulating layer 100.

The plurality of conductive adhesive members 600 may be disposed between the first insulating layer 100 and the bridge substrate 500 and may electrically connect the plurality of vias 300 to the plurality of first conductive pads 520.

As described above, the plurality of vias 300 are not formed by a plating process but are formed by a printing process, thus it is not necessary to use a separate grinding process for flattening the upper surface of the vias 300, thereby reducing manufacturing costs.

In addition, by forming the via 300 and the conductive adhesive member 600 of the same material, the bonding force and conductivity between the via 300 and the conductive adhesive member 600 may be improved.

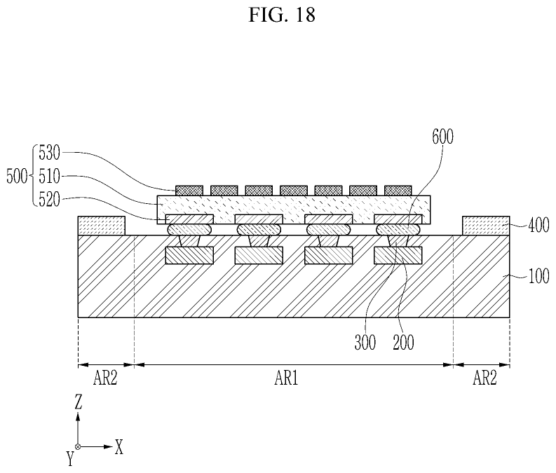

Then, a manufacturing method of a circuit board according to yet another embodiment will be described in detail below with reference to FIGS. 17 and 18 together with FIG. 16.

FIGS. 17 and 18 are cross-sectional views illustrating some steps of a manufacturing method of the circuit board of FIG. 16.

As illustrated in FIG. 17, the first insulating layer 100 may be formed, and the first circuit wiring 200 may be formed inside the first area AR1 of the first insulating layer 100.

In addition, a plurality of solder layers 40 including solder materials may be formed in the plurality of via holes VH formed in the first insulating layer 100 using a printing process.

Then, as illustrated in FIG. 18, the plurality of vias 300 may be completed by curing the plurality of solder layers 40. Furthermore, the plurality of conductive adhesive members 600 may be formed on a plurality of vias 300, respectively. The bridge substrate 500 may be positioned corresponding to the first area AR1 of the first insulating layer 100, and the plurality of first conductive pads 520 of the bridge substrate 500 and the plurality of conductive adhesive members 600 may be brought into contact with each other and pressurized to combine the plurality of first conductive pads 520 of the bridge substrate 500 and the plurality of conductive adhesive members 600.

As shown in FIG. 16, an underfill 900 may be formed to fill between the first area AR1 of the first insulating layer 100 and the bridge substrate 500. The second insulating layer 700 covering the second circuit wiring 400 and the bridge substrate 500 may be formed on the underfill 900. Additionally, the third circuit wiring 800 electrically connected to the plurality of second conductive pads 530 of the bridge substrate 500 may be formed on the second insulating layer 700.

While embodiments of the present disclosure have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A circuit board comprising:
a first insulating layer;
a first circuit wiring disposed inside a first area of the first insulating layer;
a plurality of vias connected to the first circuit wiring;
a bridge substrate disposed on the first area and having a plurality of first conductive pads;
a plurality of conductive adhesive members electrically connecting the plurality of vias to the plurality of first conductive pads; and
a second insulating layer covering the bridge substrate on the first insulating layer.

2. The circuit board of claim 1, further comprising:
an underfill filling between the first area of the first insulating layer and the bridge substrate.

3. The circuit board of claim 2, wherein:
the plurality of vias comprises a plating layer.

4. The circuit board of claim 3, wherein:
the plurality of vias are disposed inside the first insulating layer, and an upper surface of the plurality of vias is located on substantially the same plane as an upper surface of the first insulating layer.

5. The circuit board of claim 4, wherein:
the first insulating layer comprises a step area.

6. The circuit board of claim 5, wherein:
the plurality of vias protrude to the outside of the first insulating layer.

7. The circuit boar of claim 5, wherein:
a thickness of the underfill changes between an edge of the step area and an edge of the first area.

8. The circuit board of claim 4, wherein:
a side surface of the plurality of vias is in contact with the conductive adhesive member.

9. The circuit board of claim 2, wherein:
the plurality of vias comprise a solder layer.

10. The circuit board of claim 1, further comprising:
a second circuit wiring disposed on a second area of the first insulating layer; and
a third circuit wiring disposed on the second insulating layer and electrically connected to a plurality of the second conductive pads of the bridge substrate.

11. A manufacturing method of a circuit board comprising:
forming a first circuit wiring inside a first area of a first insulating layer,
forming a plurality of vias connected to the first circuit wiring,
forming a plurality of conductive members on the plurality of the vias,
contacting a first conductive pad of a bridge substrate with the plurality of conductive members, and
forming a second insulating layer covering the bridge substrate on the first insulating layer.

12. The manufacturing method of claim 11, further comprising:
forming an underfill by filling between the first area of the first insulating layer and the bridge substrate.

13. The manufacturing method of claim 12, wherein:
forming the plurality of vias comprises:
forming a plurality of via holes in the first insulating layer, and
completing the plurality of vias by forming a plurality of via layers protruding above an upper surface of the first insulating layer in the plurality of via holes through a plating process.

14. The manufacturing method of claim 13, wherein:
forming the plurality of vias further comprises completing the plurality of vias by removing the plurality of via layers protruding above the upper surface of the first insulating layer through a grinding process, and
an upper surface of the plurality of vias is located on substantially the same plane as the upper surface of the first insulating layer.

15. The manufacturing method of claim 14, further comprising:
forming a step area by etching a portion of the first area of the first insulating layer.

16. The manufacturing method of claim 15, wherein:
a thickness of the underfill changes between an edge of the step area and an edge of the first area.

17. The manufacturing method of claim 15, wherein:
the plurality of vias protrude to the outside of the first insulating layer by forming the step area.

18. The manufacturing method of claim 11, wherein:
forming the plurality of vias comprises forming a plurality of via holes in the first insulating layer and completing the plurality of vias by forming a solder layer in the plurality of the via holes through a printing process, and
an upper surface of the plurality of vias is disposed on substantially the same plane as an upper surface of the first insulating layer.

19. The manufacturing method of claim 11, further comprising:
forming a second circuit wiring on a second area of the first insulating layer; and
forming a third circuit wiring electrically connected to a plurality of the second conductive pads of the bridge substrate on the second insulating layer.
